(19) United States
(12) Patent Application Publication
(10) Pub. No.: US 2003/0155905 A1
(43) Pub. Date: Aug. 21, 2003

(54) Device, amperemeter and motor vehicle

(76) Inventor: Henning Hauenstein, Reutlingen (DE)

Correspondence Address: KENYON & KENYON, ONE BROADWAY, NEW YORK, NY, 10004, US

(21) Appl. No.: 10/258,338

(22) PCT Filed: Jan. 16, 2002
(86) PCT No.: PCT/DE02/00101

(30) Foreign Application Priority Data
Feb. 20, 2001 (DE) 101 07 811.0

(51) Int. Cl. G01R 33/00

(52) U.S. Cl. 324/117 R

(57) ABSTRACT

A device, an ammeter, and a motor vehicle are described.

For measuring the electrical current intensity in an electrical conductor (1), at least one sensor means (15) and a first section (10) of the conductor (1) and a second section (20) of the conductor (1) are provided, the directions of the current in the first section and second sections (10, 20) being antiparallel, and the sensor means (15) being situated between the first and the second section (10, 20).

### BACKGROUND INFORMATION

The precise measurement of the current intensity in a conductor through which current flows at least intermittently is required in many situations. An example in the automotive field, for example, is the determination of electrical parameters of generators and electrical drives during the operation of these units. A contactless, low-loss, and potential-free measurement of the electric current is necessary in these cases.

Shunt resistors are currently used in the related art for measuring electric currents. The high power loss in the shunt resistor, in particular at high currents, and its additional internal inductance are undesirable. In addition, a potential-free state between the measuring circuit and the main circuit cannot be ensured.

In addition, magnetic field sensors, for example Hall sensors, lateral magnetotransistors, magnetoresistive resistors, etc., are able to precisely measure the magnetic field effect of a conductor through which current flows. Particularly advantageous are the electrical isolation between the measuring circuit and the main circuit, little or no power loss, and the absence of variables which influence the current to be measured, such as inductive feedback or resistance, for example.

A problem with the use of magnetic field sensors for measuring current, however, is the existence of interference fields or stray fields originating from the current conductor to be measured or from nearby current conductors, or caused by rotating magnetic fields present in the environment of generators. Thus, it is difficult to discriminate between the magnetic field to be measured and parasitic stray fields in the environment.

One known measure for avoiding such difficulties is the shielding of the magnetic field sensor from interfering magnetic fields and the concentration of the magnetic field to be measured, using a magnetic circuit. However, shielding for highly sensitive sensors is very complicated and expensive. Magnetic circuits are likewise expensive, and also require a large amount of installation space; furthermore, it is difficult to install them. An additional disadvantage of magnetic circuits is that they tend to become saturated, thereby introducing non-linearity, between the current intensity and the magnetic field strength, into the measurement.

### ADVANTAGES OF THE INVENTION

In contrast, the device according to the present invention, the ammeter according to the present invention, and the motor vehicle according to the present invention having the features characterized in the independent claims have the advantage over the related art that, even in an electromagnetic environment under heavy load from stray fields, the electromagnetic field of a conductor through which current flows is easily measurable. It is particularly advantageous here that the measurement amplification is based not on a subsequent electrical amplification, but instead on optimization of the measurement conditions. In addition, frequency-dependent changes in the magnetic field (skin effect) may be at least partially eliminated by the conductor geometry so that they need not be taken into account using a costly intelligent evaluation circuit. Furthermore the proposed conductor geometry allows the current sensors to be installed in a manner which is not critically dependent on calibration.

Advantageous refinements of and improvements on the device, ammeter, and motor vehicle described in the independent claims are made possible by the measures listed in the subclaims.

It is particularly advantageous that the conductor is essentially horseshoe-shaped in a first conductor region, thus forming a first horseshoe shape, the first section forming a portion of the one leg of the first horseshoe shape, and the second section forming a portion of the second leg of the first horseshoe shape. The self-inductance of the conductor is therefore small, because no closed current loops are used.

It is also advantageous that a second sensor means, a third section of the conductor, and a fourth section of the conductor are provided, the directions of the current in the third and fourth sections being antiparallel, and the second sensor means being provided between the third and the fourth section. The measurable magnetic field of the conductor is thus amplified by at least a factor of 4 without the use of an additional magnetic field concentrator. Amplification occurs solely as the result of a special shaping of the current conductor and by the use of at least two identical sensor means connected back to back. Any manufacturing or technology-related signal offset may thus be eliminated. In addition, at least partial compensation is provided for temperature dependencies of the sensor means, such as temperature-dependent leakage current, offset, etc.

### DRAWING

Exemplary embodiments of the present invention are illustrated in the drawing and explained in more detail in the description below.

FIG. 1 shows a perspective illustration of an electrical conductor;

FIG. 2 shows a side view of the electrical conductor;

FIG. 3 shows a front view of the electrical conductor;

FIG. 4 shows the current conductor with an example for mounting the sensor means;

FIG. 5 shows a first embodiment of a cross section through the conductor and the sensor means; and

FIG. 6 shows a second embodiment of a cross section through the conductor and the sensor means.

### DESCRIPTION OF THE EXEMPLARY EMBODIMENTS

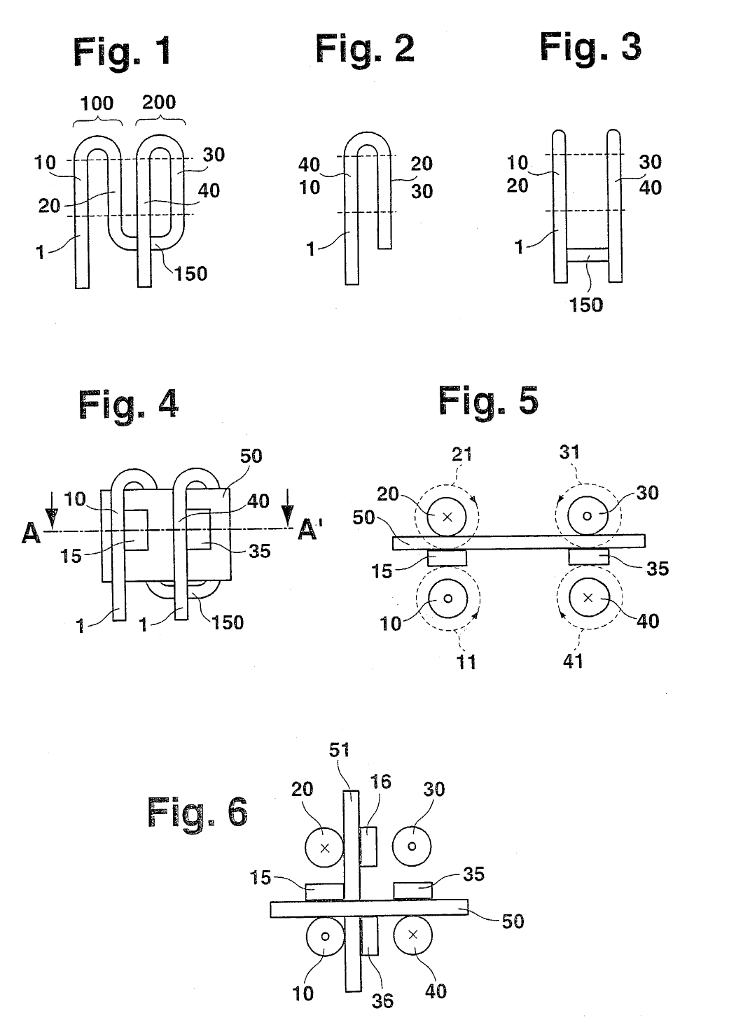

FIGS. 1, 2, and 3 illustrate an electrical conductor 1 in various views. According to the present invention conductor 1 includes a plurality of sections, a first section being denoted by reference number 10, a second section by reference number 20, a third section by reference number 30, and a fourth section by reference number 40. Conductor 1 also includes a first conductor region 100 which is essentially horseshoe-shaped. First conductor region 100 includes first section 10 and second section 20. The horseshoe shape in first conductor region 100 is produced by the following configuration: First conductor region 100 includes, in addition to first section 10 and second section 20, a connecting section which, is essentially semicircular and at the ends of which first section 10 and second section 20 each are joined as legs of the horseshoe shape created by first conductor region 100. Second conductor region 200 is similarly provided with a horseshoe shape by third section 30, fourth section, and an additional connecting section. Together with the two conductor regions 100, 200, electrical conductor 1 includes four ends of two horseshoe shapes, of which according to the present invention two ends of different conductor regions 100, 200 are connected to one another by a connecting piece 150 in such a way that both conductor regions 100, 200 are connected together and the other two ends of the horseshoe shapes created by conductor regions 100, 200 are used as the incoming line or outgoing line. Intermediate piece 150 in particular is likewise essentially semicircular. In particular according to the present invention, both conductor regions 100, 200 are situated next to one another and identically oriented. According to the present invention the conductor cross section in particular is circular, although in principle rectangular and square cross sections are also possible.

FIG. 4 illustrates conductor 1 with examples of mounting of sensor means. Conductor 1 is again illustrated having sections 10, 20, 30, and 40, second and third sections 20, 30 being hidden by the perspective illustration of a mounting plate 50. A first sensor means 15 and a second sensor means 35 are situated on mounting plate 50. Connecting piece 150 is also illustrated.

FIG. 5 illustrates a first embodiment of a cross section through conductor 1 and sensor means 15, 35. The sectional representation in FIG. 5 results from a section of the system in FIG. 4 along sectional line A-A′ shown there. The cross section in FIG. 5 is illustrated in a top view of the system, conductor sections 10, 20, 30, and 40 being visible. First section 10 is used as the current inlet, and first section 10 is thus provided in FIG. 5 with a dot in its interior to clarify that the direction of the current in first section 10 is oriented coming out of the plane of the drawing toward the viewer. Fourth section 40 is provided as the current outlet. Fourth section 40 is provided here with a cross in its interior to indicate that the direction of the current in this case is into the plane of the drawing. This produces the orientations for a first magnetic field line 11 which indicates the magnetic field surrounding first section 10 and which, due to the direction of the current in first section 10 coming out of the plane of the drawing, is oriented in a counterclockwise direction. A second magnetic field line 21 having a clockwise orientation is illustrated surrounding second section 20 indicating, as does the cross in second section 20, that the direction of the current in the second section is oriented into the plane of the drawing. In third section 30 the current again comes out of the plane of the drawing, and thus a third magnetic field line 31 having a counterclockwise orientation is illustrated surrounding third section 30, indicating that the direction of the current here is oriented coming out of the plane of the drawing. A fourth magnetic field line 41 is illustrated surrounding fourth section 40. The orientations of magnetic field lines 11, 21, 31, and 41 are indicated by arrows which are not identified more precisely by reference numbers. It can be seen that first sensor means 15 illustrated in FIG. 5 is positioned in the center between first section 10 and second section 20. The directions of the current in sections 10 and 20 are antiparallel on account of the essentially parallel alignment of first section 10 with respect to second section 20 and the different direction of the current in first section 10 compared to second section 20. As a result, the magnetic fields created by the current flow in the two sections 10, 20 become superimposed (constructive superimposition) at the site of first sensor means 15, i.e., in the center between first and second sections 10, 20, and are amplified. The same occurs at the site of second sensor means 35 with regard to third section 30 and fourth section 40. In addition, it can be seen that the resulting magnetic field strengths at the site of first sensor means 15 are oppositely oriented with respect to that of second sensor means 35. Using sensor means 15, 35, the measurement signal of which is positive or negative depending on the direction of the magnetic field, and mounting these sensors in the same orientation on mounting plate 50, the one sensor means measures a positive magnetic field and the other sensor means measures a negative magnetic field. Both measurement signals are then subtracted from one another in an evaluation circuit, not shown, resulting in a doubling of the total signal. A direct back to back connection of the output signals of both sensors is also possible. Overall, the quadrupled signal is measured in this case compared to the case of a single sensor on a linear current conductor.

With its first conductor region 100 and its second conductor region 200, conductor 1 may also be described as a double U shape. A circular cross section of the conductor is advantageous because the magnetic field created by current flow through the conductor is thus independent of the frequency of the current. In rectangular conductors, the skin effect results in a frequency-dependent deformation of the current flow. The current density on the conductor surface then increases, resulting in large spatial variations in the magnetic field distribution. This is not the case in conductor 1, which has a circular cross section. Depending on the application, the diameter of conductor 1 is chosen according to the intensity of the flowing current and the internal inductance to be minimized. The distances between each of sections 10, 20, 30, and 40 are chosen according to the present invention so that a mutual influence or interaction is minimized.

As already mentioned, the magnetic field strength doubles at the site of sensor means 15 or 35 as a result of the opposite or antiparallel orientation of the current direction in first and second sections 10, 20 or in third and fourth sections 30, 40. According to the present invention, magnetic field sensors are used as sensor means 15, 35 which are sensitive to a magnetic field running parallel to the sensor surface. This is the case for lateral magnetotransistors, for example. For sensors which are sensitive to a magnetic field running perpendicular to the sensor surface, it is necessary only to appropriately select the mounting position for the sensors. Back to back connection of the two magnetic field sensors in association with the special conductor geometry (double U shape) according to the present invention provides the additional advantage that, if the magnetic field sensors have a signal offset that is manufacturing—or process technology-related, this offset must either be avoided by an appropriately complex process control or subsequently compensated for by the evaluation circuit when a single sensor is used. Using two magnetic field sensors having a comparable signal offset, for example by suitable preselection during production, this offset is compensated for by the back to back connection. Any temperature dependencies of the offset are also eliminated automatically. The sensor system according to the present invention has the additional advantage that conductor 1 may be used as shielding from stray and interference fields. Protection is thus provided from undesired magnetic fields above and below the sensor. In addition, magnetic interference fields which run parallel to mounting plate 50 and which in principle would react sensitively to sensor means 15, 35 are compensated for due to the fact that these interference fields are compensated for by the back to back connection of the sensors. According to the present invention, the system results in a high degree of insensitivity to parasitic interference fields and stray fields. The minimum distance between sensor means 15, 35 is limited only by the required diameter of the conductor for the main circuit. The distance between sensor means 15, 35 is typically several millimeters to a few centimeters.

The selected conductor geometry also offers manufacturing-related advantages for installation. Mounting plate 50 may be very precisely mounted by suitably shaping it to fit the U-shaped current conductor. To this end, semicircular grooves or recesses (not shown), for example, are provided on the upper edge of mounting plate 50. The sensors are then laterally positioned relative to the current conductor by preassembling the sensors on structured mounting plate 50. In principle, the positioning of sensor means 15, 35 exactly in the center between first section 10 and second section 20, or between third section 30 and fourth section 40, would be critical. It is important here to find the center exactly, since at that point the structurally superimposed magnetic field is at a maximum. To ensure a precise and reproducible installation here as well, mounting plate 50 may be placed, for example, with one side on each of two sections 10, 20, 30, and 40, or two mounting plates may be provided between which sensor means 15, 35 are situated and which, together with sensor means 15, 35, exactly occupy the respective spaces between each of two sections 10, 20, 30, and 40. Flip chip assembly techniques, ASIC integration, and the like, for example, are suitable for this second possibility. Costly and complex precision mounting is thus avoided using the illustrated self-adjusting mounting plate.

The evaluation circuit, not illustrated, should be positioned as close as possible to sensor means 15, 35 in order to minimize interferences during signal transmission between the sensor site and the evaluation site. It is possible here to provide the evaluation circuit on the mounting plate.

In addition, according to the present invention the entire system is packed, so that only optionally elongated sections 10, 20, 30, and 40 for the supply and discharge of current project from the housing and in addition the terminals for the evaluation circuit are accessible, or otherwise the conductor geometry including mounting plate 50 is packed with casting compound, for example. According to the present invention, such a packed sensor unit is referred to as an ammeter. Such an ammeter is then integrated into the main circuit of an application, for example the phase conductor of a generator, in particular by using suitable adaptors or by insertion, soldering, welding, etc.

The use of packing also makes it possible-to provide shielding from stray and interference fields. Since the magnetic field of the current conductor and the sensor means necessary for measurement are situated inside the ammeter, by using shielding material the interior may be easily encapsulated from the outside environment in the event that the above-described structurally-dictated shielding effect of the system is not sufficient. This could be the case with stray fields which exhibit strong spatial non-uniformity or which fluctuate rapidly. As a shielding packing, according to the present invention a specialized melting compound or casting compound is provided which prevents external interference fields from being introduced. It is also possible to provide cladding or damping for the entire ammeter, using shielding materials such as protective foil, μ metal, etc.

FIG. 6 shows a second embodiment of the system according to the present invention including conductor geometry and sensor means. In addition to first sensor means 15 and second sensor means 35, a third sensor means 16 and a fourth sensor means 36 are provided, third sensor means 16 being situated between second section 20 and third section 30, and fourth sensor means 36 being situated between first section 10 and fourth section 40, and third sensor means 16 and fourth sensor means 36 being situated on an additional mounting plate 51.

Using evaluation techniques, the measurement signals from first sensor means 15 and second sensor means 35 are subtracted from one another, and the measurement signals from third sensor means 16 and fourth sensor means 35 are subtracted from one another, and these results are then added together. An 8-fold signal is obtained compared to a single straight conductor, whereby, as described above, the sensor pair including first sensor means 15 and second sensor means 35 and the sensor pair including third sensor means 16 and fourth sensor means 36 each mutually compensate for offset, temperature, and stray fields.

What is claimed is:

1. A device for measuring the electrical current intensity in an electrical conductor (1) having at least one sensor means (15) and a first section (10) of the conductor (1) and a second section (20) of the conductor (1), the directions of the current in the first section and second sections being antiparallel, and the sensor means (15) being provided between the first and the second section (10, 20).

2. The device as recited in claim 1,
wherein the first section (10) and the second section (20) run essentially parallel to one another in the region of highest sensitivity of the sensor means (15).

3. The device as recited in claim 1 or 2,
wherein the conductor (1) is essentially horseshoe-shaped in a first conductor region (100), thus forming a first horseshoe shape, the first section (10) forming one portion of the one leg of the first horseshoe shape and the second section (20) forming a portion of the other leg of the first horseshoe shape.

4. The device as recited in claim 1 or 2,
wherein a second sensor means (35), a third section (30) of the conductor (1), and a fourth section (40) of the conductor (1) are provided, the directions of the current in the third and fourth sections (30, 40) being antiparallel, and the second sensor means (35) being provided between the third and the fourth section (30, 40).

5. The device as recited in claim 4,
wherein the conductor (1) is essentially horseshoe-shaped in a second conductor region (200), thus forming a second horseshoe shape, and the third section (30) forms a portion of the one leg of the second horseshoe shape and the fourth section (40) forms a portion of the other leg of the second horseshoe shape, and one leg of the first horseshoe shape and one leg of the second horseshoe shape are connected.

6. The device as recited in one of the preceding claims,
wherein the cross section of the conductor is circular.

7. The device as recited in one of the preceding claims,
wherein a magnetic field sensor, in particular a Hall sensor, a lateral magnetotransistor, and/or a magnetoresistive resistor, is as the sensor means (15, 35).

8. An ammeter having a device as recited in one of the preceding claims.

9. A motor vehicle having a device or an ammeter as recited in one of the preceding claims.
